(19) United States
(12) Patent Application Publication
(10) Pub. No.: US 2007/0044941 A1
(43) Pub. Date: Mar. 1, 2007

(54) Heatsink having porous fin

(76) Inventor: Ching-Lin Kuo, Taichung City (TW)

Correspondence Address: LEONG C LEI, PMB # 1008, 1867 YGNACIO VALLEY ROAD, WALNUT CREEK, CA, 94598, US

(21) Appl. No.: 11/213,760

(22) Filed: Aug. 30, 2005

(51) Int. Cl. H05K 7/20

(52) U.S. Cl. 165/80.3; 361/704; 165/907

(57) ABSTRACT

A heatsink for electronic component is provided. The heatsink has its fins made from metallic plates having multiple cavities of irregular shapes and dimensions dispersed within the metallic plates. For fins made from these porous metallic plates, the cavities or pores significantly increase the surface areas of the fins exposed to the air and these fins, therefore, have a superior heat dissipation capability than those fins made of the same material but with no pores. When operated with an auxiliary fan, the pores of the fins provide additional passages to the air flow and the fins are able to achieve a better wind-chill effect.

### BACKGROUND OF THE INVENTION

(a) Technical Field of the Invention

The present invention generally relates to heatsinks, and more particularly to heatsinks whose fins are made from metallic plates having a plurality of pores.

(b) Description of the Prior Art

As shown in FIG. 3, a conventional heatsink usually contains multiple thin narrow plates 20 called fins, and the fins 20 are densely arranged in an array on the heatsink. The heatsink and its fins 20 are usually made of metallic materials having a high thermal conductivity. The heatsink is usually installed on top of an electronic component (e.g., an integrated circuit chip) and the heat produced by the electronic component is conducted to the fins 20 of the heatsink and dissipated to the air. As such, the electronic component and other near-by components will not become damaged or malfunctioned from the high temperature caused by the accumulation of heat.

It should be obvious that the reason why the fins 20 of a heatsink are constructed as such is to increase their surface area exposed to the air so that more heat could be dissipated more quickly. This conventional technique has been proven to be an effective thermal control solution. However, it should also be obvious that the conventional technique has a certain limitation in terms of the number of fins 20 and the surface area of the fins 20. In other words, with the foregoing conventional structure, to increase a heatsink's heat dissipation capability beyond its inherent limitation can only rely on the selection of a superior material (i.e., with better thermal conductivity) for the heatsink and fins. This approach inevitably increases the production cost of the heatsinks and, therefore, most manufacturers usually employ an auxiliary fan (as shown in FIG. 3) to increase the air flow and, consequently, the heat dissipation capability of the heatsinks.

### SUMMARY OF THE INVENTION

The primary purpose of the present invention is to provide a heatsink structure which conquers the inherent limitation of conventional heatsinks using thin narrow fins without resorting to the use of expensive materials.

A heatsink according to the present invention has its fins made from metallic plates having multiple cavities of irregular shapes and dimensions dispersed within the metallic plates. For fins made from these porous plates, these cavities or pores significantly increase the surface areas of the fins exposed to the air and these fins, therefore, have a superior heat dissipation capability than those fins made of the same material but with no pores. When operated with an auxiliary fan, the pores of the fins provide additional passages to the air flow and the fins are able to achieve a better wind-chill effect.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective schematic view showing a metallic plate used to fabricate the fins of a heatsink according to an embodiment of the present invention.

FIG. 2 is a perspective schematic view showing a heatsink according to an embodiment of the present invention installed on a circuit board.

FIG. 3 is a perspective schematic view showing a conventional heatsink installed on a circuit board.

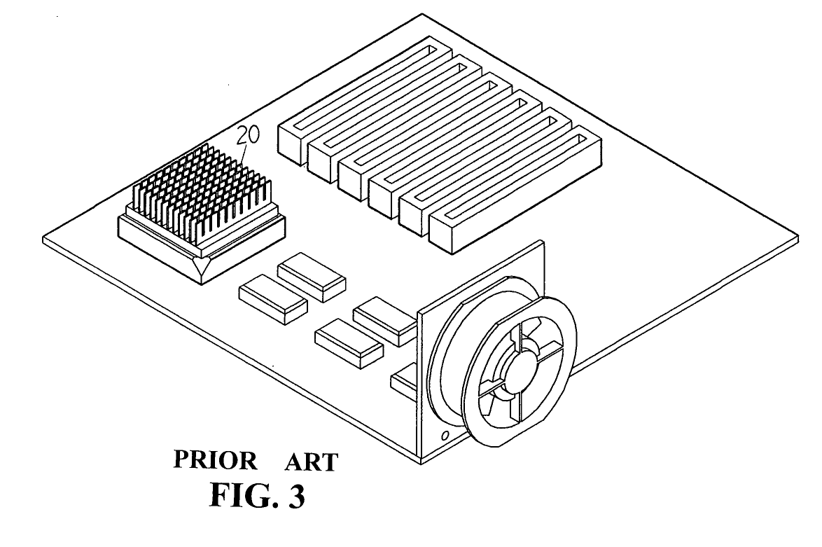

### DETAILED DESCRIPTION OF THE PREFERRED EMBODIMENTS

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

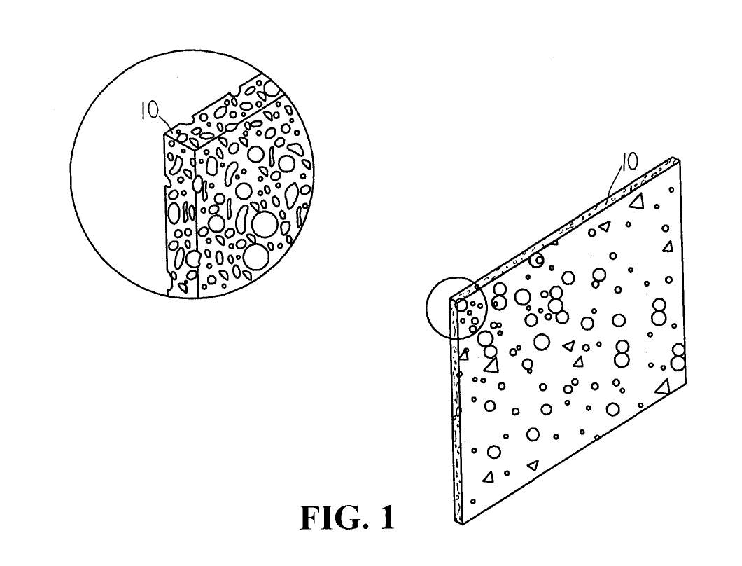

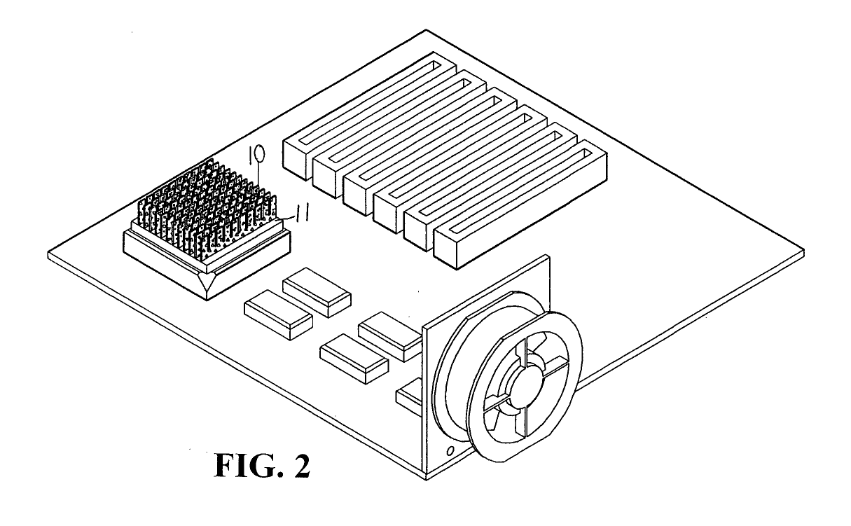

As shown in FIGS. 1 and 2, the fins 10 of a heat sink according to an embodiment of the present invention are made from metallic plates with high thermal conductivity. The metallic plates have multiple cavities or pores of irregular shapes and dimensions dispersed within the metallic plates. The porous metallic plates are appropriately cut in order to form pieces of thin and narrow fins 10. In an alternative embodiment, the porous metallic material could also be molded into the required fin arrangement. The pieces of fins 10 are attached to a positioning base 11 for installing on an electronic component.

For fins 10 made from these porous metallic plates, the cavities or pores significantly increase the surface areas of the fins 10 exposed to the air. Compared to the conventional fins 20 with no pores whose surface area to the air is constrained by the number of fins 20 and the surface area of each fin 20, the fins 10 according to the present invention, on one hand, has an increased surface area several times larger with the embedded pores and, on the other hand, the heatsink could allow more fins 10 on the base 11 with narrower spacing between the fins 10.

These fins 10, therefore, have a superior heat dissipation capability than those fins 20 made of the same material but with no pores. When operated with an auxiliary fan, the pores on the fins 10 provides additional passages to the air flow and are able to achieve a better wind-chill effect. Another benefit for having pores in the fins is that the weight of the heatsink could also be reduced. In addition to the embodiment shown in FIG. 2, an alternative embodiment could use a solid block made of the same porous metallic material for heat dissipation, instead of having multiple thin and narrow fins 11. The pores in the block provide the required exposure to the air. In general, the rigidity of the metallic materials allow the fabrication of heatsinks according to the present invention into various shapes by appropriate cutting or pressing so as to fit the special requirements from different applications (such as for heat dissipation in computing devices, electrical appliances, etc.).

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A heatsink comprising a plurality of fins made from a metallic material having a plurality of pores dispersed within said metallic material by pressing or cutting, wherein said pores increases the surface area of said fins exposed to the air, allows the gaps between said fins to be decreased, and reduces the weight of said heatsink.

2. A heatsink comprising a block made from a metallic material having a plurality of pores dispersed within said metallic material, wherein said pores increases the surface area of said block exposed to the air and reduces the weight of said heatsink.
